(19) United States
(12) Patent Application Publication
(10) Pub. No.: US 2026/0094624 A1
(43) Pub. Date: Apr. 2, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yi Ching ONG, Hsinchu (TW); KUO-CHING HUANG, Hsinchu (TW); Yu-Sheng CHEN, Hsinchu (TW)

(73) Assignee: Taiwan Semiconductor Manufacturing Company, Ltd., Hsinchu (TW)

(21) Appl. No.: 18/901,850

(22) Filed: Sep. 30, 2024

(51) Int. Cl. G11C 5/06; G11C 5/08; H10B 61/00; H10N 50/01; H10N 50/10

(52) U.S. Cl. CPC G11C 5/063; G11C 5/08; H10B 61/22; H10N 50/01; H10N 50/10

(57) ABSTRACT

A semiconductor device and a manufacturing method thereof are provided. The semiconductor device includes a logic block and a p-bit block. The logic block includes a plurality of plurality of logic elements. The p-bit block includes a transistor, a first bit cell with a magnetic structure and at least one second bit cell with a resistance structure. The first bit cell with the magnetic structure is connected to one end of the transistor. The at least one second bit cell with the resistance structure is connected to another end of the transistor.

### BACKGROUND

The disclosure relates in general to a device and a manufacturing method thereof, and more particularly to a semiconductor device and a manufacturing method thereof.

Real quantum device commercialization & miniaturization is still in the far future. Current computation method for quantum problem using GPU is very taxing on computing power. MTJ p-bit was proposed to be an intermediate, but a more practical solution. MTJ p-bit was demonstrated using discrete device, no integrated device was available yet.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a probabilistic computing device according to one embodiment of the present disclosure.

FIG. 2 shows a detail structure of the magnetic structure according to one embodiment of the present disclosure.

FIG. 3 shows a probabilistic computing device according to another embodiment of the present disclosure.

FIG. 4 shows a circuit diagram of a probabilistic computing device according to one embodiment of the present disclosure.

FIG. 5 shows a top view of part of the probabilistic computing device shown in the FIG. 4 according to one embodiment of the present disclosure.

FIG. 6 shows a probabilistic computing device according to another embodiment of the present disclosure.

FIG. 7 shows a top view of the probabilistic computing device shown in the FIG. 6 according to another embodiment of the present disclosure.

FIG. 8 shows a probabilistic computing device according to another embodiment of the present disclosure.

FIG. 9 shows a top view of the probabilistic computing device shown in the FIG. 8 according to another embodiment of the present disclosure.

FIGS. 10A to 10C illustrate a manufacturing method of the probabilistic computing device shown in the FIG. 2.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

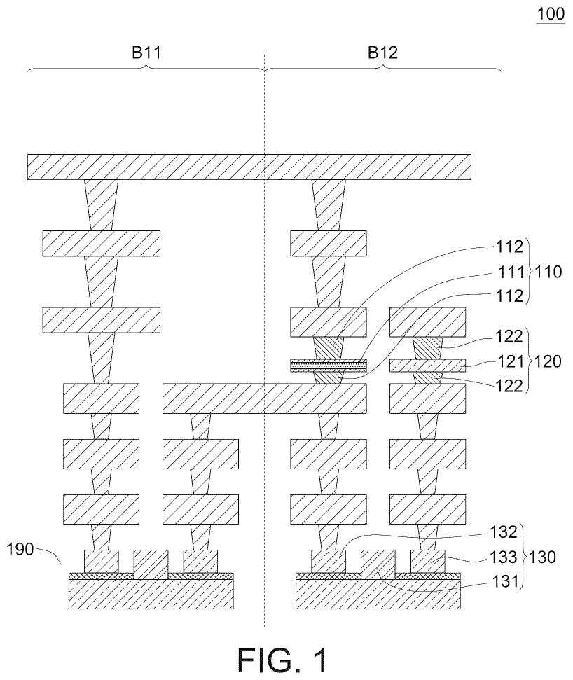

In the embodiments of the present disclosure, MTJ based structure and layout as the basic block in probabilistic computing ASIC is disclosed. Please refer to FIG. 1, which shows a probabilistic computing device 100 according to one embodiment of the present disclosure. The probabilistic computing device 100 is an integrated solution for probabilistic computing. The probabilistic computing device 100 includes a logic block B11 and a p-bit block B12. The p-bit block B12 is adjacent to the logic block B11. The logic block B11 includes a plurality of logic elements 190. The logic element 190 is, for example, controller or digital to along converter. The p-bit block B12 includes a transistor 130, a first bit cell 110 and a second bit cell 120.

In one embodiment of the present disclosure, the logic block B11 including the logic elements 190 and the p-bit block B12 including the transistor 113, the first bit cell 111 and the second bit cell 112 are co-existed in an identical semiconductor structure. The logic block B11 and the p-bit block B12 are semiconductor structures, and are not discrete electronic elements.

The transistor 130 is, for example, an N-Metal-Oxide-Semiconductor (NMOS) transistor. For example, the transistor 130 includes a first end 131, a second end 132 and a third end 132. The first end 131 is a gate, the second end 132 is of the source and drain, and the third end 133 is another one of the source and drain. Source/drain region(s) may refer to a source or a drain, individually or collectively dependent upon the context.

The first bit cell 110 is, for example, a Magnetic Tunnel Junction (MTJ) element. For example, the first bit cell 110 includes a magnetic structure 111 and two metal layers 112. The magnetic structure 111 is disposed between the two metal layers 112. The magnetic structure 111 includes, but not limited to, Co, Fe, B. For example, the magnetic material of the magnetic structure 111 could include FeCoB. The material of the metal layers 112 could be TiN, Mo or TaN.

The second bit cell 120 is, for example, a resistor. For example, the second bit cell 120 includes a resistance conductor layer 121 and two metal layers 122. The resistance conductor structure 121 is disposed between the two metal layers 122. The material of the resistance conductor structure 121 could be TiN, Mo or TaN. The material of the metal layers 122 could be TiN, Mo or TaN.

In the present disclosure, the logic elements 190, the transistor 113, the first bit cell 111 and the second bit cell 112 are co-existed in an identical semiconductor structure.

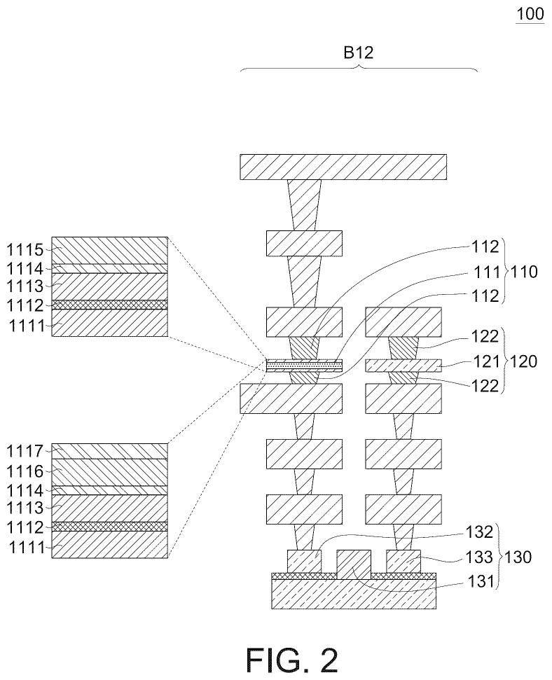

Please refer to FIG. 2, which shows a detail structure of the magnetic structure 111 according to one embodiment of the present disclosure. In one embodiment, the magnetic structure 111 may include a pinned layer 1111, a Ruderman-Kittel-Kasuya-Yosida (RKKY) spacer 1112, a reference layer 1113, a tunnel barrier 1114 and a free layer 1115. The pinned layer 1111, the reference layer 1113 and the free layer 1115 are magnetic material layers. The RKKY spacer 1112 and the tunnel barrier 1114 are oxide material layers. The Total thickness of the magnetic material layers is less than 30 nm. The Total thickness of the oxide material layers is less than 5 nm. Total thickness of the metal layer 112 sandwiching the magnetic layers and the oxide material layers is less than 40 nm.

In another embodiment, the magnetic structure 111 may include a pinned layer 1111, a Ruderman-Kittel-Kasuya-Yosida (RKKY) spacer 1112, a reference layer 1113, a tunnel barrier 1114, a composite or single FL 1116 and a cap oxide 1117. The pinned layer 1111, the reference layer 1113 and the composite or single FL 1116 are magnetic material layers. The RKKY spacer 1112, the tunnel barrier 1114 and the cap oxide 1117 are oxide material layers. The Total thickness of the magnetic material layers is less than 30 nm. The Total thickness of the oxide material layers is less than 5 nm. Total thickness of the metal layer 112 sandwiching the magnetic layers and the oxide material layers is less than 40 nm.

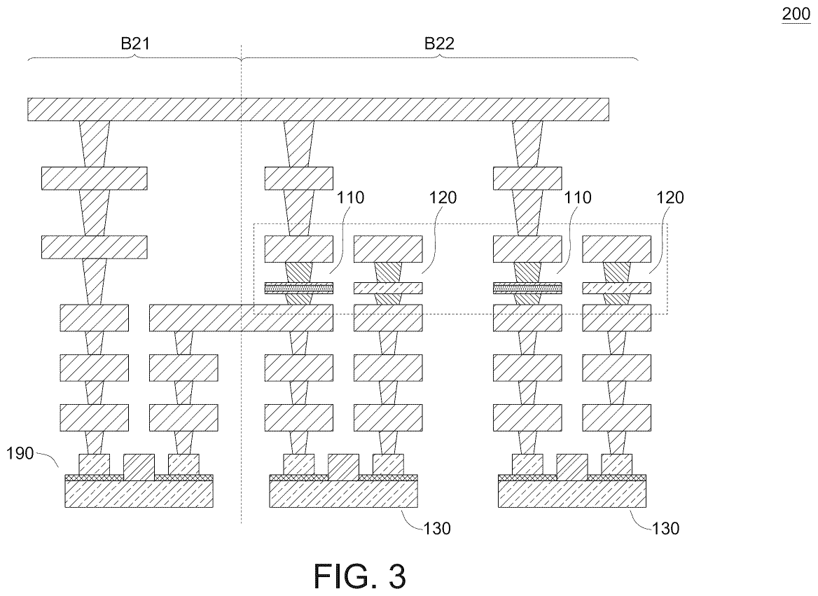

Please refer to FIG. 3, which shows a probabilistic computing device 200 according to another embodiment of the present disclosure. The probabilistic computing device 200 includes a logic block B21 and a p-bit block B22. The p-bit block B12 includes, for example, two transistors 130, two first bit cells 110 and two second bit cells 120. The number of the transistors 130, the number of the first bit cells 110 and the number of the second bit cells 120 are not used to limit the present invention.

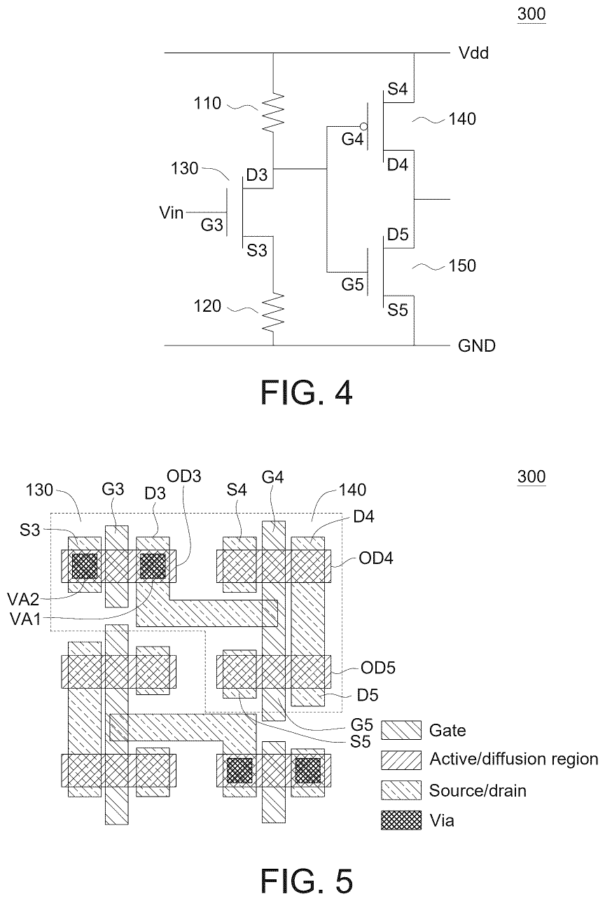

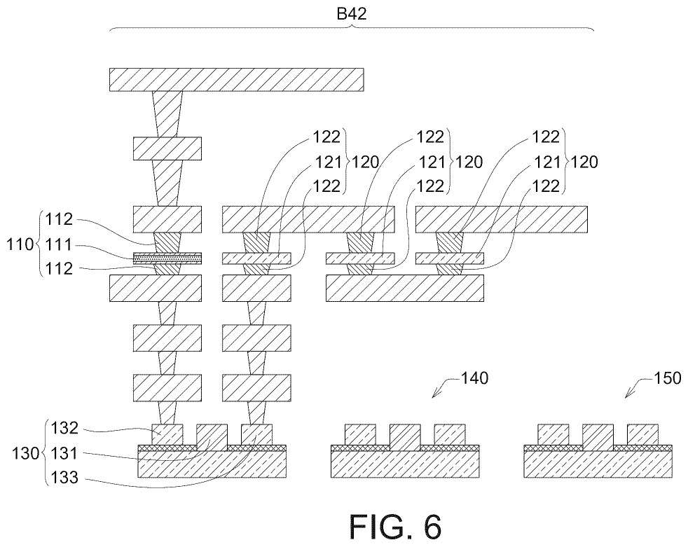

Please refer to FIGS. 4 and 5. FIG. 4 shows a circuit diagram of a probabilistic computing device 300 according to one embodiment of the present disclosure. FIG. 5 shows a top view of part of the probabilistic computing device 400 according to one embodiment of the present disclosure. The circuit diagram and the top view are used to give examples and are not used to limit the present invention. As shown in the example of FIG. 4, the transistor 130 is, for example, a NMOS transistor. A gate G3 of the transistor 130 is connected to an inputting voltage Vin. A source S3 of the transistor 130 is connected to the second bit cell 120 without the magnetic structure. A drain D3 of the transistor 130 is connected to the first bit cell 110 with the magnetic structure 111 (shown in FIG. 1). The second bit cell 120 is connected to a common voltage or a ground voltage GND. The first bit cell 110 is connected to a supply voltage Vdd. The drain D3 of the transistor 130 is also connected to a transistor 140 and a transistor 150. The transistor 140 is, for example, a PMOS transistor. The transistor 150 is, for example, a NMOS transistor. The drain D3 of the transistor 130 is connected to a gate G4 of the transistor 140 and a gate G5 of the transistor 150. A drain D4 of the transistor 140 is connected to a drain D5 of the transistor 150. A source S5 of the transistor 150 is connected to the common voltage or the ground voltage GND. A source S4 of the transistor 140 is connected to the supply voltage Vdd.

As shown in the FIG. 5, in the transistor 130, the gate G3, the source S3 and the drain D3 are disposed above the active/diffusion region OD3. In the transistor 130, the via VA1 is disposed on the drain D3 to connect to the first bit cell 110 and the via VA2 is disposed on the source S3 to connected to the second bit cell 120. In the transistor 140, the gate G4, the source S4 and the drain D4 are disposed above the active/diffusion region OD4. The drain D3 of the transistor 130 is connected to the gate G4 of the transistor 140 and the gate G5 of the transistor 150. In the transistor 150, the gate G5, the source S5 and the drain D5 are disposed above the active/diffusion region OD5. The drain D4 of the transistor 140 and the drain D5 of the transistor 150 are connected together.

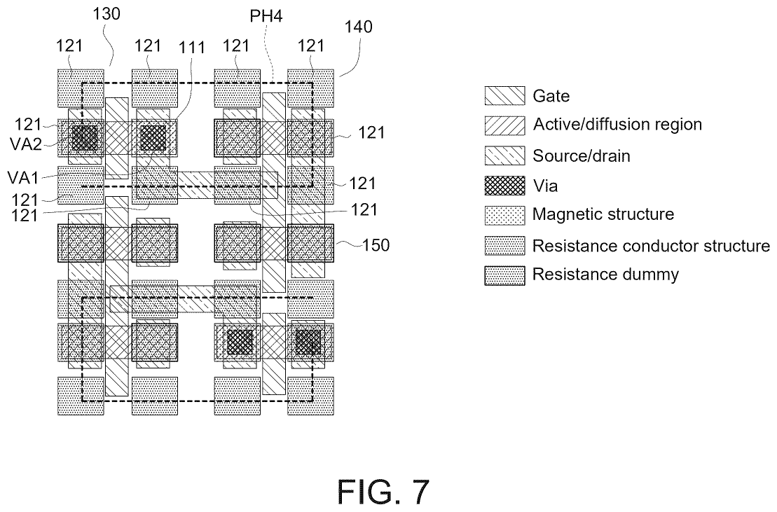

Please refer to FIG. 6, which shows a probabilistic computing device 400 according to another embodiment of the present disclosure. As shown in the example of the FIG. 6, the p-bit block B42 includes one transistor 130, one first bit cells 110 and more than one second bit cells 120. The first bit cell 110 with the magnetic structure 111 and the second bit cells 120 with the resistance conductor structure 121 have identical dimension.

For predetermined resistance value, the quantity of the second bit cells 120 could be more than one, and the second bit cells 120 form a daisy chain connection. In one embodiment, the quantity of the second bit cells 120 is larger than 2 and less than 10.

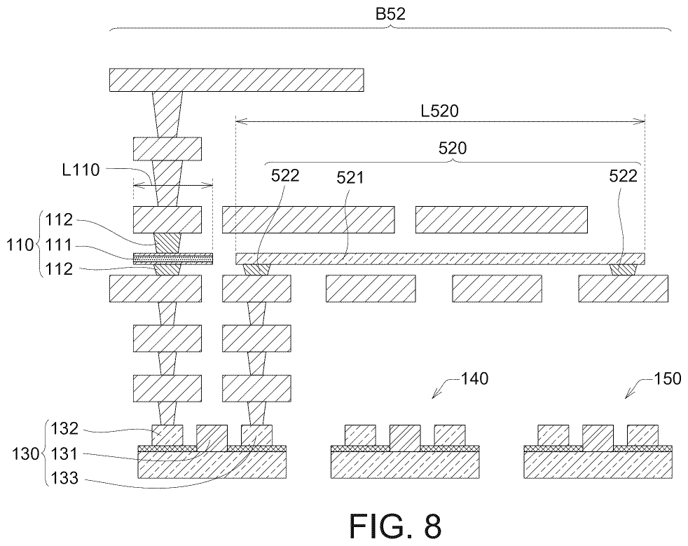

Please refer to FIG. 7, which shows a top view of the probabilistic computing device 400 according to another embodiment of the present disclosure. As shown in the FIG. 7, the magnetic structure 111 of the first bit cell 110 is disposed on the via VA1 and one resistance conductor structure 121 of the second bit cell 120 is disposed on the via VA2. Other resistance conductor structures 121 of the other second bit cells 120 are disposed along a path PH4. Those resistance conductor structures 121 are located at the same height.

To saving space, the path PH4 could be ring shaped and overlaps part of the transistor 140. That is to say, some of the resistance conductor structures 121 may overlap part of the transistor 140.

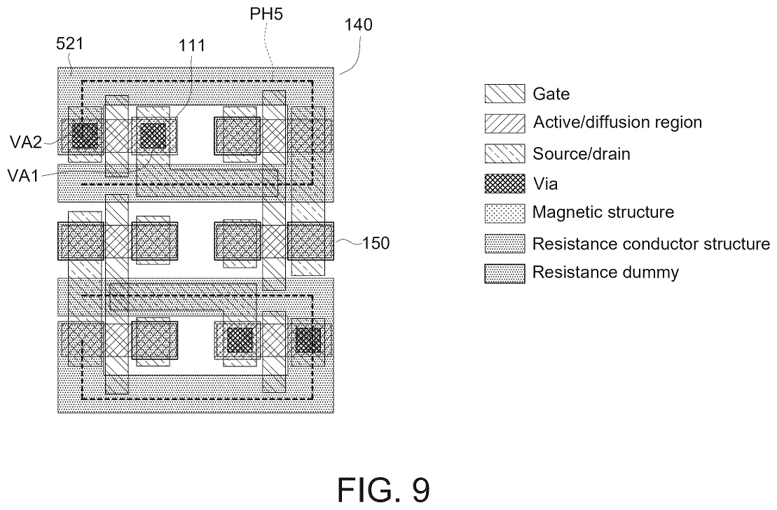

FIG. 8, which shows a probabilistic computing device 500 according to another embodiment of the present disclosure. As shown in the example of the FIG. 8, the p-bit block B52 includes one transistor 130, one first bit cells 110 and one second bit cell 520. The first bit cell 110 with the magnetic structure 111 and the second bit cell 520 with the resistance conductor structure 521 have different dimensions.

For predetermined resistance value, the second bit cell 520 is expended and disposed on two metal layers 522. The resistance conductor structurer 521 forms a thin film connection. In one embodiment, a length L520 of the second bit cell 520 is 2 to 100 times larger than a length L110 of the first bit cell 110.

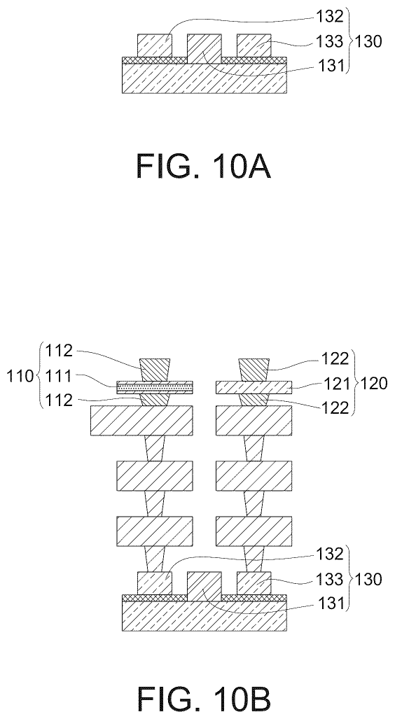

Please refer to FIG. 9, which shows a top view of the probabilistic computing device 500 according to another embodiment of the present disclosure. As shown in the FIG. 9, the magnetic structure 111 of the first bit cell 110 is disposed on the via VA1 and one resistance conductor structure 521 of the second bit cell 520 is disposed on the via VA2. The resistance conductor structure 521 of the second bit cells 520 is extended along a path PH5. Those resistance conductor structure 521 is extended at the same height.

To saving space, the path PH5 could be ring shaped and overlaps part of the transistor 140. That is to say, part of the resistance conductor structure 521 may overlap part of the transistor 140.

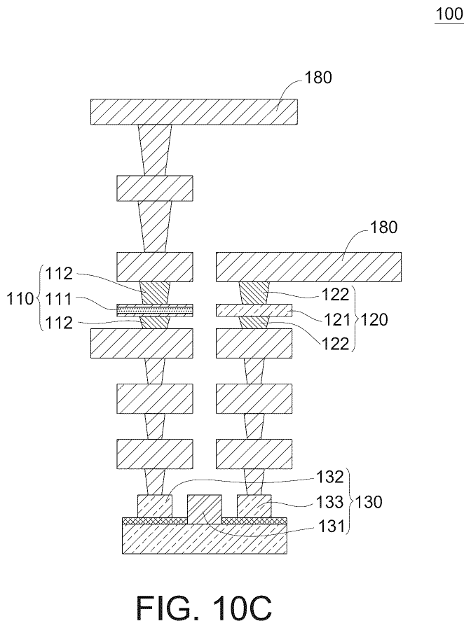

Please refer to FIGS. 10A to 10C, which illustrate a manufacturing method of the probabilistic computing device 100. As shown in the FIG. 10A, the transistor 130 is formed.

Then, the first bit cell 110 with the magnetic structure 111 connected to one end of the transistor 130 and the second bit cell 120 with the resistance conductor structure 121 connected to another end of the transistor 130 are formed. In one embodiment of this disclosure, the first bit cell 110 with the magnetic structure 111 and the second bit cell 120 with the resistance conductor structure 121 are simultaneously formed.

Afterwards, a conducting structure 180 is formed to connect the first bit cell 110 and the second bit cell 120.

According to the embodiments described above, new devices for realizing p-bit on ASIC are provided. This device enhances computing power without increasing transistor counts. This disclosure proposes a device structure which can be the basic block for probabilistic computing or quantum computing ASIC. The disclosed structure can be identified by having a MRAM bit cell connected to one end of the transistor and MRAM bit cell without the magnetic layers connected to the other end of the transistor. This disclosure is important to the semiconductor industry to extend the scope of spintronics to high performance computing field.

This disclosure proposes a device structure to enable fabrication of 1 to 5 nm crystalline ferroelectric material within CMOS process thermal constraint. Existing crystalline ferroelectric film cannot be thinner than 5 nm. This disclosure has additional benefit in gaining extra area from the contour surface of the diamond shape source/drain epitaxy. The disclosed structure is 1 to 5 nm single or multi crystalline film with (perovskite, orthorhombic, or any non-centrosymmetric crystal structure) directly in contact to transistor's source/drain.

This disclosure proposes a device structure to enable fabrication of a ferroelectric memory cell with storage of more than 1 bit by using mature implant process to adjust doping concentration. The signature of the disclosed structure is multi dopant profile in the semiconductor layer of the metal-ferroelectric-semiconductor capacitor, be it at the FEOL or BEOL of the IC. This is critical to cover the scope of device structures for multi-bit FTJ.

According to one example embodiment, a semiconductor device is provided. The semiconductor device includes a logic block and a p-bit block. The logic block includes a plurality of plurality of logic elements. The p-bit block includes a transistor, a first bit cell with a magnetic structure and at least one second bit cell with a resistance structure. The first bit cell with the magnetic structure is connected to one end of the transistor. The at least one second bit cell with the resistance structure is connected to another end of the transistor.

Based on the semiconductor device described in the previous embodiments, the p-bit block is adjacent to the logic block.

Based on the semiconductor device described in the previous embodiments, the logic block and the p-bit block are co-existed in a semiconductor structure.

Based on the semiconductor device described in the previous embodiments, the first bit cell with the magnetic structure and the at least one second bit cell with the resistance structure are co-existed in a semiconductor structure.

Based on the semiconductor device described in the previous embodiments in the first bit cell, the magnetic structure is disposed between two metal layers; and in each of the at least one second bit cell, the resistance structure is disposed between two metal layers.

Based on the semiconductor device described in the previous embodiments, wherein a quantity of the at least one second bit cell is more than one, and the second bit cells form a daisy chain connection.

Based on the semiconductor device described in the previous embodiments, the quantity is larger than 2 and less than 10.

Based on the semiconductor device described in the previous embodiments, the first bit cell with the magnetic structure and the at least one second bit cell with the resistance structure have identical dimension.

Based on the semiconductor device described in the previous embodiments, the first bit cell with the magnetic structure and the at least one second bit cell with the resistance structure have different dimensions.

Based on the semiconductor device described in the previous embodiments, a quantity of the at least one second bit cell is one, a length of the second bit cell is 2 to 100 times larger than a length of the first bit cell.

According to one example embodiment, a semiconductor device is provided. The semiconductor device includes a plurality of logic elements, a transistor, a first bit cell and at least one second bit cell. The transistor is a CMOS transistor having a source and a drain. The first bit cell is connected to one of the source and the drain. The first bit cell is a Magnetic Tunnel Junction (MTJ) element. The at least one second bit cell is connected to another one of the source and the drain. The at least one second bit cell is a resistor. The first bit cell and the at least one second bit cell are co-existed in a semiconductor structure.

Based on the semiconductor device described in the previous embodiments, the logic elements, the transistor, the first bit cell and the at least one second bit cell are co-existed in a semiconductor structure.

Based on the semiconductor device described in the previous embodiments, in the first bit cell, a magnetic structure is disposed between two metal layers; and in each of the at least one second bit cell, a resistance structure is disposed between two metal layers.

Based on the semiconductor device described in the previous embodiments, a quantity of the at least one second bit cell is more than one, and the second bit cells form a daisy chain connection.

Based on the semiconductor device described in the previous embodiments, a quantity of the second cells is larger than 2 and less than 10.

Based on the semiconductor device described in the previous embodiments, the first bit cell and the at least one second bit cell have identical dimension.

Based on the semiconductor device described in the previous embodiments, the first bit cell and the at least one second bit cell have different dimensions.

Based on the semiconductor device described in the previous embodiments, a quantity of the at least one second bit cell is one, a length of the second bit cell is 2 to 100 times larger than a length of the first bit cell.

According to one example embodiment, a manufacturing method of a semiconductor device is provided. The manufacturing method of the semiconductor device includes: forming a transistor; and forming a first bit cell with a magnetic structure connected to one end of the transistor and at least one second bit cell with a resistance structure connected to another end of the transistor.

Based on the semiconductor device described in the previous embodiments, the first bit cell with the magnetic structure and the at least one second bit cell with the resistance structure are simultaneously formed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a logic block, including a plurality of plurality of logic elements;
a p-bit block, including:
a transistor;
a first bit cell with a magnetic structure connected to one end of the transistor; and
at least one second bit cell with a resistance structure connected to another end of the transistor.

2. The semiconductor device according to claim 1, wherein the p-bit block is adjacent to the logic block.

3. The semiconductor device according to claim 1, wherein the logic block and the p-bit block are co-existed in a semiconductor structure.

4. The semiconductor device according to claim 1, wherein the first bit cell with the magnetic structure and the at least one second bit cell with the resistance structure are co-existed in a semiconductor structure.

5. The semiconductor device according to claim 1, wherein in the first bit cell, the magnetic structure is disposed between two metal layers; and in each of the at least one second bit cell, the resistance structure is disposed between two metal layers.

6. The semiconductor device according to claim 1, wherein a quantity of the at least one second bit cell is more than one, and the second bit cells form a daisy chain connection.

7. The semiconductor device according to claim 6, wherein the quantity is larger than 2 and less than 10.

8. The semiconductor device according to claim 1, wherein the first bit cell with the magnetic structure and the at least one second bit cell with the resistance structure have identical dimension.

9. The semiconductor device according to claim 1, wherein the first bit cell with the magnetic structure and the at least one second bit cell with the resistance structure have different dimensions.

10. The semiconductor device according to claim 1, wherein a quantity of the at least one second bit cell is one, a length of the second bit cell is 2 to 100 times larger than a length of the first bit cell.

11. A semiconductor device, comprising:
a plurality of logic elements; and
at least one transistor, which is a CMOS transistor having a source and a drain;
a first bit cell, connected to one of the source and the drain, wherein the first bit cell is a Magnetic Tunnel Junction (MTJ) element; and
at least one second bit cell, connected to another one of the source and the drain, wherein the at least one second bit cell is a resistor, and the first bit cell and the at least one second bit cell are co-existed in a semiconductor structure.

12. The semiconductor device according to claim 11, wherein the logic elements, the transistor, the first bit cell and the at least one second bit cell are co-existed in a semiconductor structure.

13. The semiconductor device according to claim 11, wherein in the first bit cell, a magnetic structure is disposed between two metal layers; and in each of the at least one second bit cell, a resistance structure is disposed between two metal layers.

14. The semiconductor device according to claim 13, wherein a quantity of the at least one second bit cell is more than one, and the second bit cells form a daisy chain connection.

15. The semiconductor device according to claim 14, wherein a quantity of the second cells is larger than 2 and less than 10.

16. The semiconductor device according to claim 11, wherein the first bit cell and the at least one second bit cell have identical dimension.

17. The semiconductor device according to claim 11, wherein the first bit cell and the at least one second bit cell have different dimensions.

18. The semiconductor device according to claim 11, wherein a quantity of the at least one second bit cell is one, a length of the second bit cell is 2 to 100 times larger than a length of the first bit cell.

19. A manufacturing method of a semiconductor device, comprising:
forming a transistor; and
forming a first bit cell with a magnetic structure connected to one end of the transistor and at least one second bit cell with a resistance structure connected to another end of the transistor.

20. The manufacturing method of the semiconductor device according to claim 19, wherein the first bit cell with the magnetic structure and the at least one second bit cell with the resistance structure are simultaneously formed.
